(19) United States
(12) Patent Application Publication
(10) Pub. No.: US 2013/0032915 A1
(43) Pub. Date: Feb. 7, 2013

(54) SOLID STATE IMAGING DEVICE AND METHOD FOR MANUFACTURING THE SAME

(71) Applicants: Junichi TONOTANI, Kanagawa-ken (JP); Takayoshi FUJII, Kanagawa-ken (JP); Kenji SASAKI, Kanagawa-ken (JP); Yusaku KONNO, Kanagawa-ken (JP)

(72) Inventors: Junichi TONOTANI, Kanagawa-ken (JP); Takayoshi FUJII, Kanagawa-ken (JP); Kenji SASAKI, Kanagawa-ken (JP); Yusaku KONNO, Kanagawa-ken (JP)

(73) Assignee: Kabushiki Kaisha Toshiba, Tokyo (JP)

(21) Appl. No.: 13/564,382

(22) Filed: Aug. 1, 2012

(30) Foreign Application Priority Data
Aug. 3, 2011 (JP) 2011-170144

(51) Int. Cl. H01L 31/0232; H01L 31/18

(52) U.S. Cl. 257/432; 438/69; 257/E31.127

(57) ABSTRACT

According to one embodiment, a solid state imaging device includes a substrate, and a plurality of interference filters. The substrate includes a plurality of photoelectric conversion units. The plurality of interference filters is provided individually for the plurality of photoelectric conversion units. The plurality of interference filters includes a plurality of layers with different refractive indices stacked. The plurality of interference filters is configured to selectively transmit light in a prescribed wavelength range. A space is provided between adjacent ones of the interference filters.

### CROSS-REFERENCE TO RELATED APPLICATIONS

This application is based upon and claims the benefit of priority from the prior Japanese Patent Application No. 2011-170144, filed on Aug. 3, 2011; the entire contents of which are incorporated herein by reference.

### FIELD

Embodiments described herein relate generally to a solid state imaging device and method for manufacturing the same.

### BACKGROUND

Advances to finer pixels (increasing the number of pixels) and lower profiles (downsizing) are being made in solid state imaging devices such as CMOS (complementary metal oxide semiconductor) image sensors and CCD (charge coupled device) image sensors.

Hence, a solid state imaging device is proposed that includes an interference filter which is more suitable for finer pixels and lower profiles than color filters using conventionally used organic pigments.

In the interference filter, a problem of color mixing occurs by obliquely incident light being mixed into an adjacent pixel region.

Thus, a solid state imaging device is proposed that includes a light blocking unit at the periphery of the interference filter.

However, if a light blocking unit is provided at the periphery of the interference filter, the proportion of the light blocking unit in the pixel area may be large, or light may be absorbed into the light blocking unit, possibly leading to a decrease in sensitivity. Furthermore, since a process of providing the light blocking unit is needed, complicated manufacturing processes and an increase in manufacturing costs may be caused.

### BRIEF DESCRIPTION OF THE DRAWINGS

FIG. 1 is schematic cross-sectional views for illustrating solid state imaging devices according to a first embodiment. And FIG. 1 is the case of a back-side illumination solid state imaging device 1.

FIG. 2 is schematic cross-sectional views for illustrating solid state imaging devices according to a first embodiment. And FIG. 2 is the case of a front-side illumination solid state imaging device 11.

FIG. 3 is a schematic view for illustrating the conditions of the optical simulations.

FIG. 4 is a graph for illustrating optical simulation results in the case where the interference filter 4 is formed using silicon oxide.

FIG. 5 is a graph for illustrating optical simulation results in the case where the interference filter 4 is formed using titanium oxide.

FIG. 6 is a flow chart for illustrating methods for manufacturing solid state imaging devices according to the second embodiment.

### DETAILED DESCRIPTION

In general, according to one embodiment, a solid state imaging device includes a substrate, and a plurality of interference filters. The substrate includes a plurality of photoelectric conversion units. The plurality of interference filters is provided individually for the plurality of photoelectric conversion units. The plurality of interference filters includes a plurality of layers with different refractive indices stacked. The plurality of interference filters is configured to selectively transmit light in a prescribed wavelength range. A space is provided between adjacent ones of the interference filters.

Hereinbelow, embodiments are described with reference to the drawings. In the drawings, similar components are marked with the same reference numerals, and a detailed description thereof is omitted as appropriate.

The X direction, the Y direction, and the Z direction in the drawings represent mutually orthogonal directions; the X direction and the Y direction are directions parallel to the major surface of a substrate 20, and the Z direction is a direction (stacking direction) orthogonal to the major surface of the substrate 20.

### First Embodiment

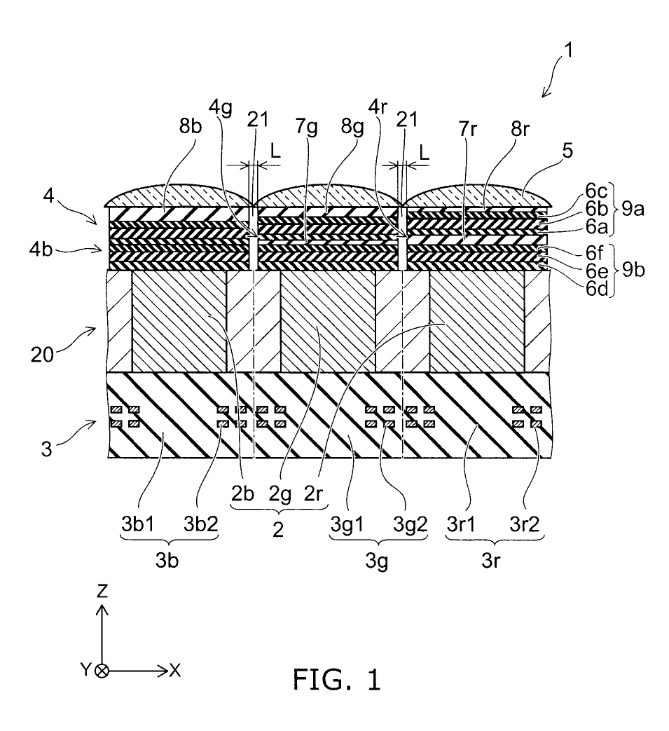

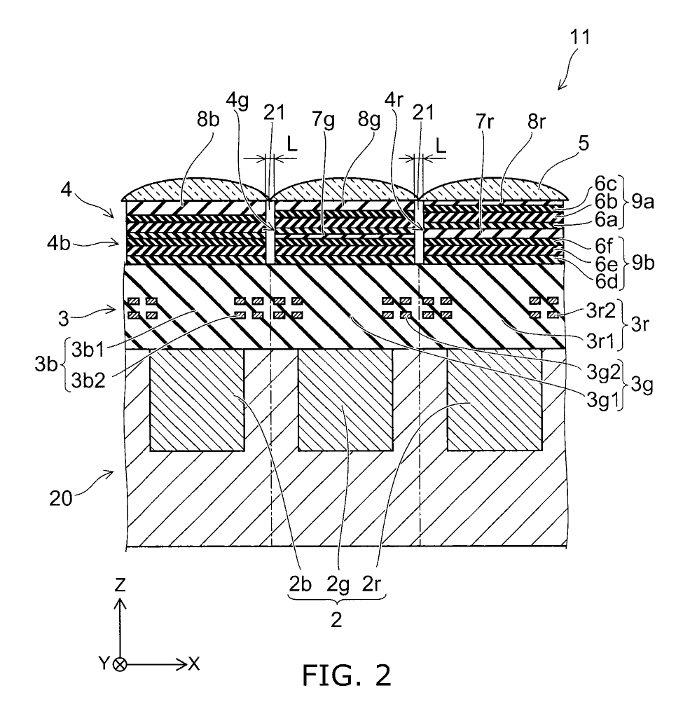

FIG. 1 and FIG. 2 are schematic cross-sectional views for illustrating solid state imaging devices according to a first embodiment. FIG. 1 is the case of a back-side illumination solid state imaging device 1, and FIG. 2 is the case of a front-side illumination solid state imaging device 11. FIG. 1 and FIG. 2 illustrate configurations of three pixels as examples.

First, the back-side illumination solid state imaging device 1 illustrated in FIG. 1 is described.

As shown in FIG. 1, the solid state imaging device 1 includes a photoelectric conversion unit 2, an interconnection unit 3, an interference filter 4, and a lens 5.

The photoelectric conversion unit 2 is provided in plural at the major surface of the substrate 20. The photoelectric conversion unit 2 may be configured to generate a charge in accordance with the intensity of incident light and store the generated charge. The photoelectric conversion unit 2 may be, for example, a photodiode including a charge storage region formed by semiconductor processes. In this case, a photoelectric conversion unit 2r may be configured to receive light in the wavelength range of red, generate a charge in accordance with the intensity of the received light, and store the charge. A photoelectric conversion unit 2g may be configured to receive light in the wavelength range of green, generate a charge in accordance with the intensity of the received light, and store the charge. A photoelectric conversion unit 2b may be configured to receive light in the wavelength range of blue, generate a charge in accordance with the intensity of the received light, and store the charge.

The photoelectric conversion units 2r, 2g, and 2b are provided in a well region formed in the substrate 20. The well region may be formed of a semiconductor (e.g. silicon) containing an impurity of a first conductivity type (e.g. the p type) at a low concentration. The p-type impurity may be, for example, boron. The charge storage region in the photoelectric conversion units 2r, 2g, and 2b may be formed of a semiconductor (e.g. silicon) containing an impurity of a second conductivity type (e.g. the n type) that is a conductivity type different from the first conductivity type. In this case, the impurity concentration of the second conductivity type in the charge storage region is set higher than the impurity concentration of the first conductivity type in the well region. The n-type impurity may be, for example, phosphorus or arsenic.

The interconnection unit 3 is provided on the opposite side of the photoelectric conversion unit 2 from the side on which light is incident. In this case, an interconnection unit 3r is provided to be related to the photoelectric conversion unit 2r. An interconnection unit 3g is provided to be related to the photoelectric conversion unit 2g. An interconnection unit 3b is provided to be related to the photoelectric conversion unit 2b. The interconnection units 3r, 3g, and 3b include insulating units 3r1, 3g1, and 3b1 and interconnection patterns 3r2, 3g2, and 3b2 formed in the insulating units 3r1, 3g1, and 3b1, respectively. The insulating units 3r1, 3g1, and 3b1 may be formed of, for example, silicon oxide or the like. The interconnection patterns 3r2, 3g2, and 3b2 may be formed in a plurality of layers (in the case of what is illustrated in FIG. 1, in two layers), for example. The interconnection patterns 3r2, 3g2, and 3b2 may be formed using, for example, a metal such as copper.

The interference filter 4 functions as a color filter that selectively guides light in the wavelength ranges of red, green, and blue out of the incident light to the photoelectric conversion unit 2. In this case, an interference filter 4r selectively guides light in the wavelength range of red out of the incident light to the photoelectric conversion unit 2r. An interference filter 4g selectively guides light in the wavelength range of green out of the incident light to the photoelectric conversion unit 2g. An interference filter 4b selectively guides light in the wavelength range of blue out of the incident light to the photoelectric conversion unit 2b.

The interference filter 4 may be a photonic crystal filter in which a layer using an inorganic material with a low refractive index and a layer using an inorganic material with a high refractive index are stacked.

That is, the interference filter 4 is provided for each of the plurality of photoelectric conversion units 2, has a configuration in which a plurality of layers with different refractive indices are stacked, and selectively transmits light in a prescribed wavelength range.

As described later, a space 21 is provided between adjacent interference filters 4.

The interference filter 4 includes an upper stacked unit 9a (corresponding to an example of a first stacked unit), a lower stacked unit 9b (corresponding to an example of a second stacked unit), and interference units 7r and 7g provided between the upper stacked unit 9a and the lower stacked unit 9b. As described later, since the film thickness of the interference unit is set in accordance with the wavelength range of light selected, there is a case where no interference unit is provided depending on the wavelength range of light.

The upper stacked unit 9a and the lower stacked unit 9b function as mirrors of which the reflection surfaces are opposed to each other, and have the center wavelength (e.g. 550 nm) in the visible light range (e.g. the wavelength range of 400 nm to 700 nm) as the center wavelength of the interference filter 4. The center wavelength of the visible light range is a wavelength at which the reflectance of the reflection surface reaches a peak.

In this case, in view of errors of the visible light range, the center wavelength may be in a range of not less than 540 nm and not more than 560 nm.

Dielectric layers with different refractive indices are alternately stacked in the upper stacked unit 9a and the lower stacked unit 9b. In the case of what is illustrated in FIG. 1, a dielectric layer 6a (corresponding to an example of a first dielectric layer), a dielectric layer 6b (corresponding to an example of a second dielectric layer), and a dielectric layer 6c (corresponding to an example of a third dielectric layer) are stacked in this order in the upper stacked unit 9a. A dielectric layer 6d (corresponding to an example of a fourth dielectric layer), a dielectric layer 6e (corresponding to an example of a fifth dielectric layer), and a dielectric layer 6f (corresponding to an example of a sixth dielectric layer) are stacked in this order in the lower stacked unit 9b. In this case, the refractive index of the dielectric layer 6a and the dielectric layer 6c is higher than the refractive index of the dielectric layer 6b, and the refractive index of the dielectric layer 6d and the dielectric layer 6f is higher than the refractive index of the dielectric layer 6e. The dielectric layer 6a, the dielectric layer 6c, the dielectric layer 6d, and the dielectric layer 6f may be formed using, for example, titanium oxide (TiO₂, refractive index: 2.5), silicon nitride (SiN, refractive index: 2.0), or the like. The dielectric layer 6b and the dielectric layer 6e may be formed using, for example, silicon oxide (SiO₂, refractive index: 1.46).

The optical film thickness of the dielectric layers 6a to 6f is set to ¼ of the center wavelength (the center wavelength of the visible light range). The optical film thickness of the dielectric layers 6a to 6f may be set to, for example, not less than 135 nm and not more than 140 nm.

In this case, the value of the optical film thickness is set to a value obtained by multiplying the physical film thickness d of a layer of the objective by the refractive index n of the material forming the layer.

Therefore, the film thickness d of the dielectric layers 6a to 6f can be expressed by the following formula.

[Mathematical Formula 1]

Where d is the film thickness of the dielectric layers 6a to 6f, n is the refractive index, and λ is the center wavelength.

For example, in the case where the center wavelength λ is 550 nm, the dielectric layer 6d is formed of titanium oxide (refractive index n being 2.5), and the dielectric layer 6e is formed of silicon oxide (refractive index n being 1.46), then the film thickness of the dielectric layer 6d is 55 nm and the film thickness of the dielectric layer 6e is 94 nm. Also the film thickness of the dielectric layers 6a, 6b, 6c, and 6f can be similarly found. However, the film thickness of the dielectric layer 6a formed on the lower stacked unit 9b side of the upper stacked unit 9a is set thinner than 55 nm.

The interference units 7r and 7g are provided between the upper stacked unit 9a and the lower stacked unit 9b, and are provided in order to cause light multiply reflected at the reflection surface of the upper stacked unit 9a and the reflection surface of the lower stacked unit 9b to interfere (multiple beam interference). The interference units 7r and 7g have a function based on the same principle as the Fabry-Perot interferometer.

The refractive index of the interference units 7r and 7g is lower than the refractive index of the dielectric layers 6a, 6c, 6d, and 6f. The interference units 7r and 7g may be formed using, for example, silicon oxide.

The film thickness of the interference, units 7r and 7g is set in accordance with the wavelength range of light selected. For example, for red light, the film thickness of the interference unit 7r is set to 85 nm; for green light, the film thickness of the interference unit 7g is set to 35 nm; and for blue light, the film thickness of the interference unit is set to 0 nm. In other words, no interference unit is provided in the case of blue light.

Planarization layers 8r, 8g, and 8b are provided between the interference filter 4 and the lens 5. Since the thickness dimension of the interference filter 4 is not uniform, the planarization layers 8r, 8g, and 8b are provided in order to make the position of the lens 5 uniform. The planarization layers 8r, 8g, and 8b are formed using a light-transmissive material such as a transparent resin or silicon oxide.

The lens 5 is provided on the planarization layers 8r, 8g, and 8b.

That is, the plurality of lenses 5 are individually provided for the plurality of interference filters 4 (the interference filters 4r, 4g, and 4b), and are each provided on the opposite side of the interference filter 4 from the side where the photoelectric conversion unit 2 is provided.

The lens 5 condenses incident light to the photoelectric conversion units 2r, 2g, and 2b. The lens 5 may be formed using, for example, a light-transmissive material such as a transparent resin.

The periphery of the lens 5 is located further on the outside of the interference filter 4 than the periphery of the interference filter 4. That is, the size of the lens 5 in the XY plane (a plane parallel to the major surface of the substrate 20) is larger than the size of the interference filter 4 in the XY plane. Such a configuration can increase the quantity of light incident on the lens 5, and can therefore increase sensitivity.

Here, when a color filter using an organic pigment is used in place of the interference filter 4, it is difficult to obtain finer pixels (increasing the number of pixels) and lower profiles (downsizing).

On the other hand, when the interference filter 4 is used, finer pixels and lower profiles can be obtained. However, when the interference filter 4 is used, the problem occurs that light obliquely incident on the interference filter 4 is mixed into an adjacent pixel region. In this case, a light blocking unit may be provided at the periphery of the interference filter 4 to suppress obliquely incident light being mixed into an adjacent pixel region. However, if a light blocking unit is provided at the periphery of the interference filter 4, the proportion of the light blocking unit in the pixel area may be large, or light may be absorbed into the light blocking unit, possibly leading to a decrease in sensitivity. Furthermore, since a process of providing the light blocking unit is needed, complicated manufacturing processes and an increase in manufacturing costs may be caused.

In view of this, the embodiment provides a space 21 between adjacent interference filters 4, and thereby suppresses light obliquely incident on the interference filter 4 being mixed into an adjacent pixel region.

In this case, the space 21 is filled with the gas (in general, air) in the environment in which the solid state imaging device 1 is provided.

For example, in the case where the gas in the space 21 is air, since the refractive index of the space 21 is the refractive index of air (n=1), light obliquely incident on the interference filter 4 is reflected at the interface between the interference filter 4 and the space 21, and the light being mixed into an adjacent pixel region is suppressed.

In this case, the space 21 may be provided also between adjacent planarization layers 8r, 8g, and 8b.

A configuration in which the space 21 reaches the substrate 20 and/or the lens 5 may be possible. However, if the space 21 is configured to reach the substrate 20, damage may be caused to the substrate 20 when forming the space 21. Furthermore, if the space 21 is configured to reach the lens 5, since the quantity of light incident on the lens 5 is decreased, sensitivity may be reduced. Therefore, the space 21 is preferably provided between adjacent interference filters 4 and between adjacent planarization layers 8r, 8g, and 8b.

The dimension ∠ in the XY plane of the space 21 (the dimension between adjacent interference filters 4) is preferably made small from the viewpoint of increasing sensitivity. On the other hand, the dimension ∠ in the XY plane of the space 21 is preferably made large from the viewpoint of suppressing light being mixed into an adjacent pixel region.

Next, the results of optical simulations of the relationship between the dimension ∠ in the XY plane of the space 21 and the transmittance of obliquely incident light are described.

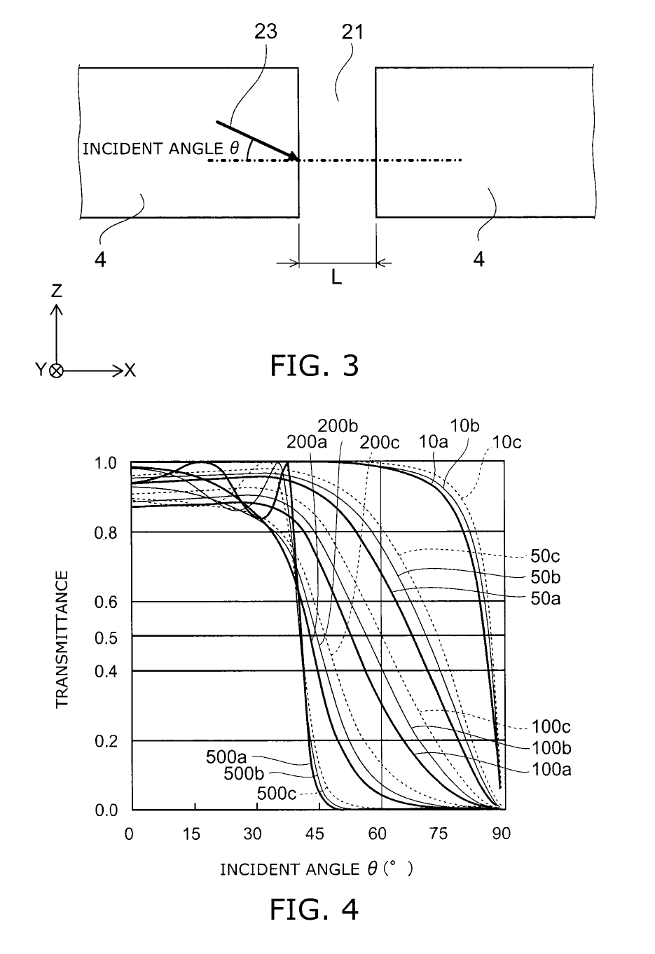

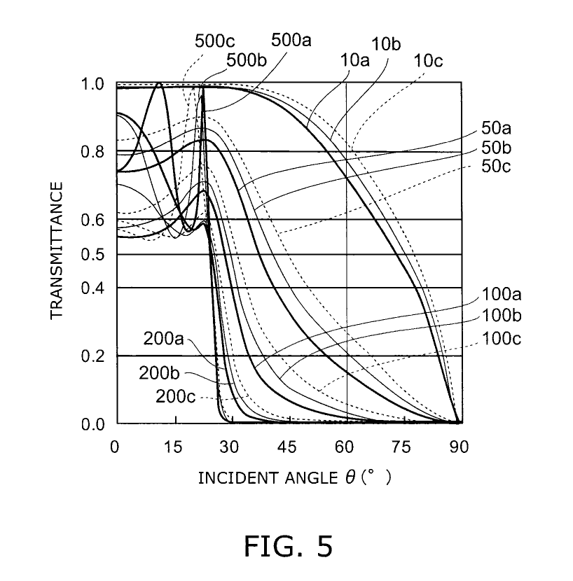

FIG. 3 is a schematic view for illustrating the conditions of the optical simulations, FIG. 4 is a graph for illustrating optical simulation results in the case where the interference filter 4 is formed using silicon oxide, and FIG. 5 is a graph for illustrating optical simulation results in the case where the interference filter 4 is formed using titanium oxide.

As shown in FIG. 3, in the optical simulations, it is assumed that the interference filter 4 is formed of only a layer using silicon oxide or titanium oxide. Furthermore, it is assumed that the refractive index of silicon oxide is 1.46, the refractive index of titanium oxide is 2.5, and the refractive index of the space 21 (air) is 1. The angle between obliquely incident light 23 and the XY plane is defined as an incident angle θ. “10” shown in FIG. 4 and FIG. 5 is the case where the dimension ∠ is 10 nm, “50” is the case where the dimension ∠ is 50 nm, “100” is the case where the dimension ∠ is 100 nm, “200” is the case where the dimension ∠ is 200 nm, and “500” is the case where the dimension ∠ is 500 nm. “a” for each dimension ∠ is the case where the wavelength of light is 450 nm, “b” is the case where the wavelength of light is 530 nm, and “c” is the case where the wavelength of light is 620 nm. For example, “10a” is the case where the dimension ∠ is 10 nm and the wavelength of light is 450 nm.

Here, from a practical viewpoint, it is preferable that the incident angle θ be 60 degrees or more and the transmittance be 50% or less (the reflectance be 50% or more).

As can be seen from FIG. 4, in the case where the interference filter 4 is formed using silicon oxide, when the dimension ∠ is set to 100 nm or more, the transmittance can be made 50% or less (the reflectance can be made 50% or more) even when the incident angle θ is 60 degrees.

As can be seen from FIG. 5, in the case where the interference filter 4 is formed using titanium oxide, when the dimension ∠ is set to 50 nm or more, the transmittance can be made 50% or less (the reflectance can be made 50% or more) even when the incident angle θ is 60 degrees.

In this case, since the interference filter 4 is a structure in which layers with different refractive indices are stacked, it is presumed that the refractive index of the interference filter 4 is the average of the different refractive indices. Therefore, it is presumed that the condition of the dimension ∠ in the XY plane of the space 21 is between those illustrated in FIG. 4 and FIG. 5.

That is, the dimension ∠ may be set to 50 nm or more, and is preferably set to 100 nm or more.

In the case where silicon nitride is used instead of titanium oxide, although the refractive index is 2.0, the preferable range of the dimension ∠ may be similar.

Next, the solid state imaging device 11 illustrated in FIG. 2 is described.

As shown in FIG. 2, the solid state imaging device 11 includes the photoelectric conversion unit 2, the interconnection unit 3, the interference filter 4, and the lens 5.

That is, the basic configuration of the front-side illumination solid state imaging device 11 is almost the same as that of the back-side illumination solid state imaging device 1 illustrated in FIG. 1 except that the positions in the Z direction of the photoelectric conversion unit 2 and the interconnection unit 3 are different.

Therefore, the interference filter 4, the space 21, the dimension ∠ in the XY plane of the space 21, the lens 5, the position of the periphery of the lens 5, etc. may be configured or set similarly to what are described above.

By the embodiment, since the space 21 is provided between adjacent interference filters 4, light obliquely incident on the interference filter 4 being mixed into an adjacent pixel region can be suppressed. Furthermore, since it is not necessary to provide a light blocking unit between adjacent interference filters 4, a decrease in sensitivity, complication of manufacturing processes, etc. can be suppressed.

Furthermore, the periphery of the lens 5 is provided on the outside of the periphery of the interference filter 4. Therefore, since the quantity of light incident on the lens 5 can be increased, sensitivity can be improved.

### Second Embodiment

Next, methods for manufacturing solid state imaging devices according to a second embodiment are illustrated.

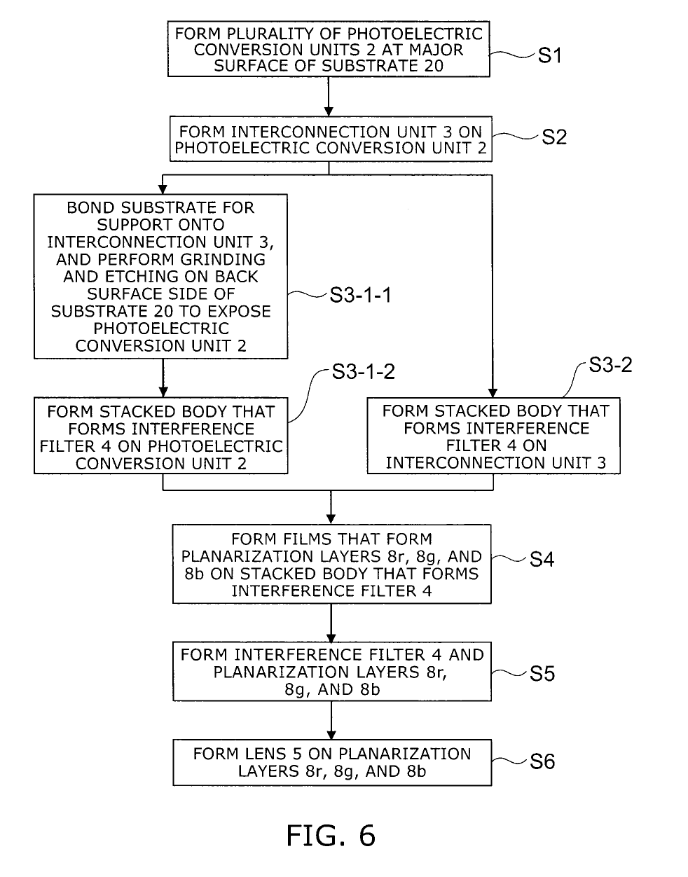

FIG. 6 is a flow chart for illustrating methods for manufacturing solid state imaging devices according to the second embodiment.

First, a plurality of photoelectric conversion units 2 are formed at the major surface of the substrate 20 (step S1).

For example, a well region is formed by using the ion implantation method to implant an impurity of the first conductivity type (e.g. the p type) into an upper portion of the substrate 20 made of silicon or the like. Then, the ion implantation method is further used to implant an impurity of the second conductivity type (e.g. the n type) that is a conductivity type different from the first conductivity type; thereby, a charge storage region of the photoelectric conversion unit 2 is formed. In this case, the impurity concentration of the second conductivity type in the charge storage region is set higher than the impurity concentration of the first conductivity type in the well region. The p-type impurity may be, for example, boron. The n-type impurity may be, for example, phosphorus or arsenic.

Next, the interconnection unit 3 is formed on the photoelectric conversion unit 2 (step S2).

For example, the sputter method, the CVD method (chemical vapor deposition method), or the like is used to deposit an insulating film of silicon oxide or the like on the photoelectric conversion unit 2. Next, a film of a metal such as copper is deposited on the insulating film deposited, and the photolithography method and the RIE (reactive ion etching) method are used to form an interconnection pattern. Then, an insulating film of silicon oxide or the like is deposited so as to cover the interconnection pattern formed; thereby, the interconnection unit 3 is formed. In the case where an interconnection pattern is formed in a plurality of layers, the deposition of the insulating film and the formation of the interconnection pattern are repeatedly performed. Vias, contacts, extension interconnections, etc. may be formed as necessary.

Next, a plurality of layers with different refractive indices are stacked to form the interference filter 4 that selectively transmits light in a prescribed wavelength range.

Here, in the case of the back-side illumination solid state imaging device 1 illustrated in FIG. 1, a substrate for support is bonded onto the interconnection unit 3 and the back surface side (the opposite side to the side where the photoelectric conversion unit 2 is provided) of the substrate 20 is ground and etched to expose the photoelectric conversion unit 2 (step S3-1-1).

Then, a stacked body that forms the interference filter 4 is formed on the photoelectric conversion unit 2 (step S3-1-2).

In the case of the front-side illumination solid state imaging device 11 illustrated in FIG. 2, a stacked body that forms the interference filter 4 is formed on the interconnection unit 3 (step S3-2).

The formation of the stacked body that forms the interference filter 4 will now be further illustrated.

In the formation of the stacked body that forms the interference filter 4, first, a stacked body that forms the lower stacked unit 9b is formed.

For example, the sputter method, the CVD method, or the like is used to stack a film that forms the dielectric layer 6d, a film that forms the dielectric layer 6e, and a film that forms the dielectric layer 6f in this order.

The films that form the dielectric layer 6d and the dielectric layer 6f may be formed using, for example, titanium oxide (TiO₂, refractive index: 2.5), silicon nitride (SiN, refractive index: 2.0), or the like. The film that forms the dielectric layer 6e may be formed using, for example, silicon oxide (SiO₂, refractive index: 1.46).

The optical film thickness of the films that form the dielectric layers 6d to 6f is set to ¼ of the center wavelength. The optical film thickness of the films that form the dielectric layers 6d to 6f may be set to, for example, not less than 135 nm and not more than 140 nm.

For example, in the case where the center wavelength λ is 550 nm, the films that form the dielectric layers 6d and 6f are formed of titanium oxide (refractive index n being 2.5), and the film that forms the dielectric layer 6e is formed of silicon oxide (refractive index n being 1.46), then the film thickness of the films that form the dielectric layers 6d and 6f is set to 55 nm and the film thickness of the film that forms the dielectric layer 6e is set to 94 nm.

Next, the sputter method, the CVD method, or the like is used to deposit a film that forms the interference unit 7r on the film that forms the dielectric layer 6f. The film thickness of the film that forms the interference unit 7r is set in accordance with the wavelength range of red light. The film thickness of the film that forms the interference unit 7r is set to 85 nm. The film that forms the interference unit 7r may be formed using, for example, silicon oxide.

Then, the photolithography method is used to form a resist pattern covering the region that forms the interference filter 4r; and the RIE method or the like is used to remove a portion of the surface of the film that forms the interference unit 7r which is exposed in the region not covered with the resist pattern. In this case, a film that forms the interference unit 7g is formed by performing half etching so that the film thickness of the film that forms the interference unit 7r may become 35 nm. After that, the resist pattern is removed, and a resist pattern is formed in which the region that forms the interference filter 4b is exposed. Then, the RIE method or the like is used to remove a portion of the film that forms the interference unit 7g which is exposed in the region that forms the interference filter 4b. After that, the resist pattern is removed; thereby, a film with a film thickness of 85 nm is formed in the region that forms the interference filter 4r, and a film with a film thickness of 35 nm is formed in the region that forms the interference filter 4g. In this case, a film that forms an interference unit is not formed in the region that forms the interference filter 4b.

Next, a stacked body that forms the upper stacked unit 9a is formed.

The upper stacked unit 9a may be formed similarly to the lower stacked unit 9b.

However, the film thickness of a film that forms the dielectric layer 6a formed on the lower stacked unit 9b side is set thinner than 55 nm.

Thus, a stacked body that forms the interference filter 4 is formed.

Next, films that form the planarization layers 8r, 8g, and 8b are formed on the stacked body that forms the interference filter 4 (step S4).

That is, the films that form the planarization layers 8r, 8g, and 8b are formed on the stacked body that forms the upper stacked unit 9a.

For example, the films that form the planarization layers 8r, 8g, and 8b may be formed by depositing a light-transmissive material such as a transparent resin or silicon oxide and using the CMP (chemical mechanical polishing) method to planarize the surface of the film deposited.

Next, the interference filter 4 and the planarization layers 8r, 8g, and 8b are formed (step S5).

For example, using the photolithography method, the dry etching method, etc., the interference filter 4 and the planarization layers 8r, 8g, and 8b having a prescribed configuration are formed from the stacked body in which the stacked body that forms the lower stacked unit 9b, the films that form the interference units 7r and 7g, the stacked body that forms the upper stacked unit 9a, and the films that form the planarization layers 8r, 8g, and 8b are stacked.

In this case, the photolithography method may be used to form a resist pattern covering the regions that form the interference filter 4 and the planarization layers 8r, 8g, and 8b; and the dry etching method may be used to remove the portion not covered with the resist pattern. Thereby, the interference filter 4 and the planarization layers 8r, 8g, and 8b having a prescribed configuration can be formed. At this time, the portion not covered with the resist pattern is removed; thereby, the space 21 is formed between adjacent interference filters 4. After that, by removing the resist pattern, the interference filter 4, the planarization layers 8r, 8g, and 8b, and the space 21 having a prescribed configuration are formed.

That is, in the process of forming the interference filter 4, the interference filter 4 is provided for each of the plurality of photoelectric conversion units 2, and the space 21 is provided between adjacent interference filters 4. In this case, the dimension ∠ in the XY plane of the space 21 (the dimension between adjacent interference filters 4) may be set to 50 nm or more.

Here, in the case where the interference filter 4 is formed of layers using silicon oxide and layers using titanium oxide, the etching rates of silicon oxide and titanium oxide can be made almost the same by, for example, plasma etching processing using a mixed gas of CF₄ and CHF₃ in which the pressure and injection power of the mixed gas are optimized. Thereby, the surface of the side wall of the interference filter 4 at which the end surfaces of two different kinds of layers are exposed can be made into a smooth planar form without unevenness. In the case where the back-side illumination solid state imaging device 1 is manufactured, the substrate 20 in which the photoelectric conversion unit 2 is formed is exposed when plasma etching processing for forming the interference filter 4 has finished. In this case, in view of the substrate 20 being formed of silicon, in regard to the etching selectivity to the silicon, an appropriate selectivity of silicon oxide to the silicon can be obtained by using known etching conditions used in contact hole etching in semiconductor processes. That is, selective plasma etching processing of the interference filter 4 to the substrate 20 is possible.

In this case, the condition and end point of the plasma etching processing can be detected by monitoring the luminescence intensity in plasma regarding titanium, silicon, oxygen, etc. produced in the plasma etching processing of titanium oxide and silicon oxide.

Next, the lens 5 is formed on the planarization layers 8r, 8g, and 8b (step S6).

That is, the lens 5 is formed on the opposite side of the interference filter 4 from the side where the photoelectric conversion unit 2 is provided.

When forming the lens 5, the periphery of the lens 5 may be located further on the outside of the interference filter 4 than the periphery of the interference filter 4.

The lens 5 may be formed by, for example, using a light-transmissive material such as a transparent resin to form the lens 5 and bonding the formed lens 5 onto the planarization layers 8r, 8g, and 8b.

Alternatively, also a method is possible in which a film that forms the lens 5 is deposited on the planarization layers 8r, 8g, and 8b using a light-transmissive material such as a transparent resin and heat treatment is performed to mold the film into the shape of the lens 5. When depositing the film that forms the lens 5, the space 21 may be filled with a sacrifice film etc. so that the light-transmissive material such as a transparent resin may not enter the space 21.

Thus, the solid state imaging devices 1 and 11 can be manufactured.

The embodiments illustrated above can suppress obliquely incident light being mixed into an adjacent pixel region, and can provide a solid state imaging device capable of suppressing a decrease in sensitivity and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

For example, in the solid state imaging devices 1 and 11, a configuration in which a plurality of pixels are arranged one-dimensionally is possible, and also a configuration in which a plurality of pixels are arranged two-dimensionally is possible. In the case of a configuration in which a plurality of pixels are arranged two-dimensionally, an interference filter 4 having a desired size and layout may be formed in accordance with the specifications of the solid state imaging devices 1 and 11. For example, pixels corresponding to light in the wavelength ranges of red, green, and blue illustrated in FIG. 1 may be laid out according to the Bayer arrangement. Furthermore, the photoelectric conversion unit 2 may be other than photodiodes. For example, an inorganic film or an organic film having a photoelectric conversion function provided between the substrate 20 and the interference filter 4 may be used. Moreover, the material, the number of stacked layers, the thickness dimension of the layers, etc. of the upper stacked unit, the interference unit, and the lower stacked unit provided in the interference filter 4 may be altered as appropriate.

What is claimed is:

1. A solid state imaging device comprising:
a substrate including a plurality of photoelectric conversion units; and
a plurality of interference filters provided individually for the plurality of photoelectric conversion units, including a plurality of layers with different refractive indices stacked, and configured to selectively transmit light in a prescribed wavelength range,
a space being provided between adjacent ones of the interference filters.

2. The device according to claim 1, wherein a dimension between the ones of the interference filters is 50 nm or more.

3. The device according to claim 1, wherein a dimension between the ones of the interference filters is 100 nm or more.

4. The device according to claim 1, further comprising a plurality of lenses provided individually for the plurality of interference filters and provided on an opposite side of the interference filter from a side where the photoelectric conversion unit is provided,
a periphery of the lens being located further on an outside of the interference filter than a periphery of the interference filter.

5. The device according to claim 1, wherein
the interference filter includes a first stacked unit and a second stacked unit,
the first stacked unit includes a first dielectric layer, a second dielectric layer provided on the first dielectric layer, and a third dielectric layer provided on the second dielectric layer,
the second stacked unit includes a fourth dielectric layer, a fifth dielectric layer provided on the fourth dielectric layer, and a sixth dielectric layer provided on the fifth dielectric layer,
a refractive index of the first dielectric layer and a refractive index of the third dielectric layer are higher than a refractive index of the second dielectric layer, and
a refractive index of the fourth dielectric layer and a refractive index of the sixth dielectric layer are higher than a refractive index of the fifth dielectric layer.

6. The device according to claim 5, wherein the second dielectric layer and the fifth dielectric layer contain silicon oxide.

7. The device according to claim 5, wherein the first dielectric layer, the third dielectric layer, the fourth dielectric layer, and the sixth dielectric layer contain titanium oxide or silicon nitride.

8. The device according to claim 5, wherein an optical film thickness of the first dielectric layer, an optical film thickness of the second dielectric layer, an optical film thickness of the third dielectric layer, an optical film thickness of the fourth dielectric layer, an optical film thickness of the fifth dielectric layer, and an optical film thickness of the sixth dielectric layer are not less than 135 nm and not more than 140 nm.

9. The device according to claim 5, further comprising an interference unit provided between the first stacked unit and the second stacked unit,
a refractive index of the interference unit being lower than a refractive index of the first dielectric layer and a refractive index of the third dielectric layer.

10. The device according to claim 9, wherein the interference unit contains silicon oxide.

11. The device according to claim 5, further comprising an interference unit provided between the first stacked unit and the second stacked unit,
a refractive index of the interference unit being lower than a refractive index of the fourth dielectric layer and a refractive index of the sixth dielectric layer.

12. The device according to claim 11, wherein the interference unit contains silicon oxide.

13. The device according to claim 1, wherein the space is filled with gas in an environment in which the device is provided.

14. The device according to claim 13, wherein the gas is air.

15. The device according to claim 4, further comprising a plurality of planarization layers provided between the plurality of interference filters and the plurality of lenses, respectively,
the space being provided between adjacent ones of the planarization layers.

16. The device according to claim 1, wherein a center wavelength of the plurality of interference filters is not less than 540 nm and not more than 560 nm.

17. The device according to claim 16, wherein an optical film thickness of the first dielectric layer, an optical film thickness of the second dielectric layer, an optical film thickness of the third dielectric layer, an optical film thickness of the fourth dielectric layer, an optical film thickness of the fifth dielectric layer, and an optical film thickness of the sixth dielectric layer are ¼ of the center wavelength.

18. A method for manufacturing a solid state imaging device comprising:
forming a plurality of photoelectric conversion units in a substrate; and
forming a plurality of interference filters including a plurality of layers with different refractive indices stacked and configured to selectively transmit light in a prescribed wavelength range,
in the forming a plurality of interference filters including a plurality of layers with different refractive indices stacked and configured to selectively transmit light in a prescribed wavelength range,
the plurality of interference filters being individually provided for the plurality of photoelectric conversion units and a space being provided between adjacent ones of the interference filters.

19. The method according to claim 18, wherein a dimension between the ones of the interference filters is 50 nm or more.

20. The method according to claim 18, further comprising providing a plurality of lenses individually for the plurality of interference filters on an opposite side of the interference filter from a side where the photoelectric conversion unit is provided,
in the providing a plurality of lenses individually for the plurality of interference filters on an opposite side of the interference filter from a side where the photoelectric conversion unit is provided,
a periphery of the lens being located further on an outside of the interference filter than a periphery of the interference filter.
